(19) United States
(12) Patent Application Publication
(10) Pub. No.: US 2009/0242894 A1
(43) Pub. Date: Oct. 1, 2009

(54) Thin-Film-Transistor Structure, Pixel Structure and Manufacturing Method Thereof

(75) Inventor: Yu-Cheng Chen, Hsinchu (TW)

Correspondence Address: James M. Wu;JW Law Group, 84 W. Santa Clara Street, Suite 820, San Jose, CA, 95113, US

(73) Assignee: AU Optronics Corp., Hsinchu (TW)

(21) Appl. No.: 12/333,809

(22) Filed: Dec. 12, 2008

(30) Foreign Application Priority Data
Mar. 26, 2008 (TW) 97110796

(51) Int. Cl. H01L 33/00; H01L 21/336; H01L 29/786

(52) U.S. Cl. 257/72; 438/158; 438/34; 257/66; 257/E21.414; 257/E33.002; 257/E29.294

(57) ABSTRACT

A thin-film-transistor (TFT) structure, a pixel structure and a manufacturing method thereof are provided. The TFT structure is formed in the pixel structure of a liquid crystal display (LCD). The TFT structure comprises a gate, a first dielectric layer, a patterned semiconductor layer, a second dielectric layer and a third dielectric layer stacked sequentially. The second dielectric layer and the third dielectric layer are formed on part of the patterned semiconductor layer to define a covered region and an uncovered region on the patterned semiconductor layer. The uncovered region of the second dielectric layer and the third dielectric layer jointly define an opening, which has at least one top lateral dimension and a bottom lateral dimension smaller than the top lateral dimension. Thereby, a lightly doped structure is formed in a portion of the covered region via the second dielectric layer after ion implantation.

This application claims the benefit of priority based on Taiwan Patent Application No. 097110796, filed on Mar. 26, 2008, the contents of which are incorporated herein by reference in their entirety.

### CROSS-REFERENCES TO RELATED APPLICATIONS

Not applicable.

### BACKGROUND OF THE INVENTION

1. Field of the Invention

This invention relates to a bottom-gate thin-film-transistor (TFT) structure formed with both a heavily and a lightly doped regions and a manufacturing method thereof without need of any additional photomask, which reduces the number of photomasks needed and the manufacturing costs. The TFT structures and the manufacturing method thereof are applied to the pixel structure of a flat panel display with TFTs, and particularly to a low temperature poly-silicon thin film transistor (LTPS TFT) with a bottom gate.

2. Descriptions of the Related Art

Low temperature poly-silicon thin-film-transistors (LTPS TFTs) have been gradually used in liquid crystal displays (LCDs). The LTPS TFTs, which have electron mobility several hundreds of times higher than that of amorphous TFTs, allow a driver IC to be fabricated on a glass substrate concurrently. Apart from reducing the cost of the driver IC, this may also reduce the number of electrical contacts between a panel and other circuit boards. As a result, the present invention remarkably increases the reliability and impact resistance of the system and mitigates the occurrence of electromagnetic interference. Furthermore, the use of LTPS TFTs may also shrink the size of the transistors to improve the resolution and increase the aperture ratio, thus further increasing the luminance of the TFT LCD panel and saving power.

In a conventional process of manufacturing a bottom-gate LTPS TFT, as restricted by the structure of the TFT, it would be difficult to form a lightly doped drain (LDD) without using an additional mask that might add to the manufacturing cost. Such a manufacturing process is described briefly as follows. A gate is formed on a substrate through a sputtering process, and then an oxide layer is deposited through a chemical vapor deposition (CVD) process. Next, a patterned poly-silicon (poly-Si) layer is formed on the oxide layer, and a heavily doped source/drain region is defined and formed on the poly-Si layer through a masking process. Subsequently, a patterned insulating layer is formed on the poly-Si layer. Using the patterned insulating layer as a mask, an ion implantation is then performed to form a lightly doped drain (LDD). Then, an interlayer dielectric layer is deposited and defined with contact windows by a lithography and etching process. Finally, a patterned metallic layer is formed to form a source electrode and a drain electrode of the TFT.

In the above steps, a mask is needed to form the heavily doped source/drain region, and at least one additional mask is needed to form the lightly doped region.

However, the additional mask(s) not only adds to the process complexity and the manufacturing cost, but also correspondingly increases the probability that a mask misalignment would occur. Once a misalignment occurs, for example, from the displacement of light rays during the lithography process, lightly doped areas different in width from each other would result on both sides. Furthermore, the slightly doped area would be formed on only one side. This would cause the deviation of electrical properties of the resulting TFT. Therefore, it is highly desirable in the art to provide a method of forming a bottom-gate LTPS transistor structure that can reduce the number of masks to simplify the manufacturing process.

### SUMMARY OF THE INVENTION

The present invention provides a bottom-gate thin-film-transistor (TFT) structure formed with a heavily doped region and a lightly doped region and a manufacturing method thereof without need of an additional photomask, which reduces the number of photomasks needed and the manufacturing costs.

One objective of the present invention is to provide a thin-film-transistor (TFT) structure formed in a liquid crystal display (LCD). By forming a second dielectric layer and a third dielectric layer sequentially on a patterned semiconductor layer, a plurality of openings are defined to partially expose the patterned semiconductor layer. Then, through the self-aligned doping process, a heavily doped region is formed in portions of the patterned semiconductor layer exposed via the openings, and a lightly doped region is formed in the patterned semiconductor layer under the exposed second dielectric layer simultaneously.

Another objective of the present invention is to provide a pixel structure formed in an LCD. The pixel structure comprises the TFT structure described above.

The present invention discloses a TFT structure comprising a gate, a first dielectric layer, a patterned semiconductor layer, a second dielectric layer and a third dielectric layer. The second dielectric layer and the third dielectric layer are partially formed on the patterned semiconductor layer to define a covered region and an uncovered region on the patterned semiconductor layer. The second dielectric layer and the third dielectric layer jointly define an opening with a bottom lateral dimension and at least one top lateral dimension, thus the uncovered region of the pattern semiconductor is exposed by the opening. The bottom lateral dimension is defined by the second dielectric layer, and the at least one top lateral dimension is defined by the third dielectric layer. The bottom lateral dimension is smaller than the at least one top lateral dimension to partially expose the second dielectric layer, thus the pattern semiconductor under the exposed second dielectric layer is defined as the covered region of the pattern semiconductor. An edge of the opening defined by the second dielectric layer is aligned approximately with an edge of the gate. Thereby, the implant ions are adapted to form a heavily doped structure in the uncovered region via the openings and form a lightly doped structure in a portion of the covered region via the second dielectric layer.

Yet a further objective of the present invention is to provide a manufacturing method of a TFT structure. The TFT structure is formed in an LCD. The method comprises the following steps: (a) forming a gate on a substrate; (b) forming a first dielectric layer to cover the gate; (c) forming a patterned semiconductor layer on the first dielectric layer overlapping the gate; (d) sequentially forming a second dielectric layer and a third dielectric layer on the patterned semiconductor layer, and partially exposing the patterned semiconductor layer on two sides of the gate by forming a plurality of openings, each of which is provided with a bottom lateral dimension and at least one top lateral dimension, wherein: the bottom lateral dimension is defined by the second dielectric layer, the at least one top lateral dimension is defined by the third dielectric layer, the bottom lateral dimension is smaller than the at least one top lateral dimension to partially expose the second dielectric layer, and an edge of the opening defined by the second dielectric layer is aligned approximately with an edge of the gate; and (e) forming a heavily doped region in the exposed patterned semiconductor layer corresponding to the openings by doping the patterned semiconductor layer, and forming a lightly doped region in the patterned semiconductor layer under the second dielectric layer that is exposed.

Still a further objective of the present invention is to provide a manufacturing method of a pixel structure. The pixel structure is formed in an LCD. The method comprises the following steps: (a) forming a first patterned conductive layer on a substrate, in which the first patterned conductive layer is formed with a gate and a first capacitor electrode; (b) forming a first dielectric layer to cover the gate and the first capacitor electrode; (c) forming a patterned semiconductor layer on the first dielectric layer to overlap the gate and the first capacitor electrode; (d) sequentially forming a second dielectric layer and a third dielectric layer on the patterned semiconductor layer, and partially exposing the patterned semiconductor layer on two sides of the gate by forming a plurality of openings, each of which is provided with a bottom lateral dimension and at least one top lateral dimension, wherein the bottom lateral dimension is defined by the second dielectric layer, the at least one top lateral dimension is defined by the third dielectric layer, the bottom lateral dimension is smaller than the at least one top lateral dimension to partially expose the second dielectric layer, and an edge of the opening defined by the second dielectric layer is aligned approximately with an edge of the gate; (e) forming a heavily doped region in the exposed patterned semiconductor layer corresponding to the openings by doping the patterned semiconductor layer, and forming a lightly doped region in the patterned semiconductor layer under a portion of the second dielectric layer that is exposed; (f) forming a second patterned conductive layer with a second capacitor electrode aligned with the first capacitor electrode both on the third dielectric layer and within the openings; (g) forming a passivation layer to cover the second patterned conductive layer and the third dielectric layer; and (h) forming a pixel electrode on the passivation layer, in which the pixel electrode is electrically connected to the second patterned conductive layer.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIGS. 1 to 8 schematically illustrate a structure of a first embodiment of this invention at various manufacturing stages; and

FIGS. 9 to 15 schematically illustrate a structure of a second embodiment of this invention at various manufacturing stages.

### DESCRIPTION OF THE PREFERRED EMBODIMENT

An LCD incorporates a display panel comprising a plurality of pixel structures. Each of the pixel structures has a TFT structure and a capacitor region, and optionally, a doped structure is formed in an appropriate region of each pixel structure. For example, a doped structure is formed in the TFT structure and/or the capacitor region of each pixel structure. According to this invention, a dielectric layer formed with openings is used as a mask for ion implantation, in which the side walls of the openings have different slopes. Through a self-aligned doping process, a doped structure with different doping concentrations is formed in the TFT structure of a pixel structure. The embodiments that are described below are only intended to illustrate rather than to limit this invention. It should be appreciated that the elements unrelated to this invention are omitted from depiction in the following embodiments and drawings.

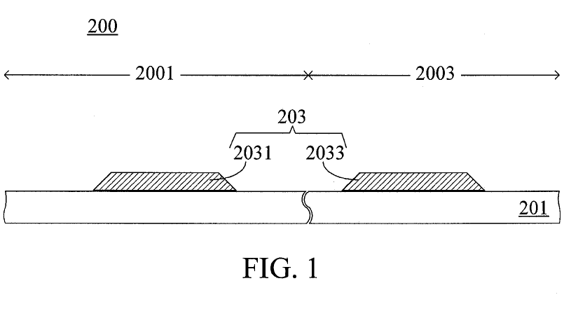

The first embodiment describes a process of forming a pixel structure in an LCD according to a method of this invention, including forming a doped structure in the pixel structure. FIGS. 1 to 8 schematically illustrate a process flow of forming the pixel structure. Initially, referring to FIG. 1, a TFT region 2001 and a capacitor region 2003 are defined in a pixel structure 200. Then, a first patterned conductive layer 203, which comprises a gate 2031 and a first capacitor electrode 2033, is formed on a substrate 201. The substrate 201 is made of a transparent material, usually of glass, quartz or other appropriate materials. Generally, a conductive material is sputtered throughout the substrate 201 to form a conductive layer (an intermediate structure up to this step is not shown in this figure). Then, an appropriate process such as lithography and etching is used to pattern the conductive layer into a first patterned conductive layer 203. The conductive material may be molybdenum (Mo), tungsten (W), chromium (Cr), aluminum (Al), copper (Cu), or a stack thereof, or other appropriate materials.

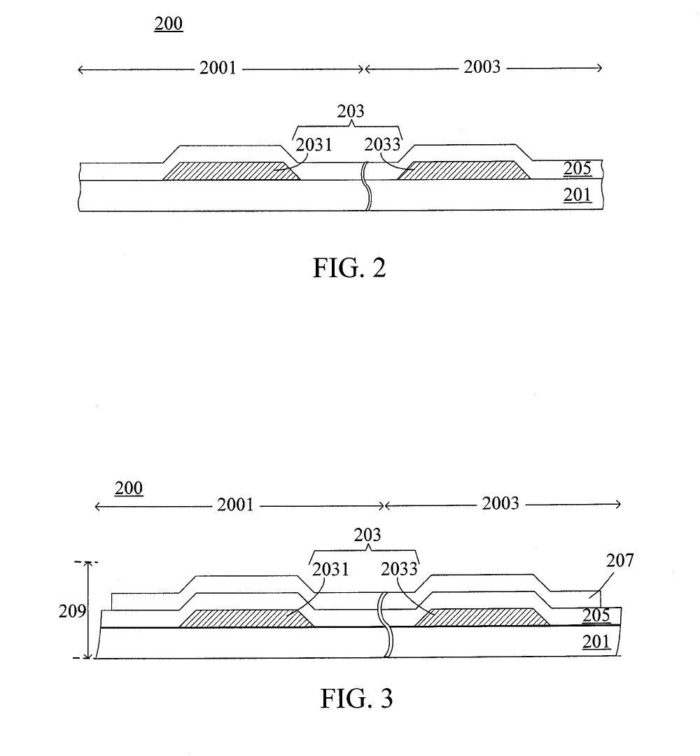

FIG. 2 illustrates a first dielectric layer 205 is formed through a deposition process to cover the first patterned conductive layer 203. The first dielectric layer 205 is usually an oxide layer, but may also be a nitride layer, other appropriate dielectric materials, or a composite of these dielectric materials. For purpose of description, an oxide layer is taken as an example in this embodiment. Generally, an appropriate material such as silane (SiH₄), nitrous oxide (N₂O) or tetra-ethyl-ortho-silicate (TEOS) can be used to form the first dielectric layer 205 on the substrate 201 through an appropriate process such as a plasma enhanced chemical vapor deposition (PECVD) to cover the first patterned conductive layer 203.

As shown in FIG. 3, a patterned semiconductor (poly-Si) layer 207 is formed on the first dielectric layer 205. Generally, an amorphous-Si layer (not shown) may be formed at first, followed by an excimer laser annealing process that recrystallizes the amorphous-Si layer into the poly-Si layer. Alternatively, a material such as Silane (SiH₄) may be reacted through a low pressure chemical vapor deposition (LPCVD) process to form the poly-Si layer. Then, an appropriate process such as lithography and etching may be used to form the patterned semiconductor layer 207, thus obtaining an underlayer 209 comprising the patterned semiconductor layer 207, the first dielectric layer 205, the first patterned conductive layer 203 and the substrate 201 from top to bottom. However, the way to form the patterned semiconductor layer 207 is not merely limited to what described above, and other appropriate processes may be also adopted.

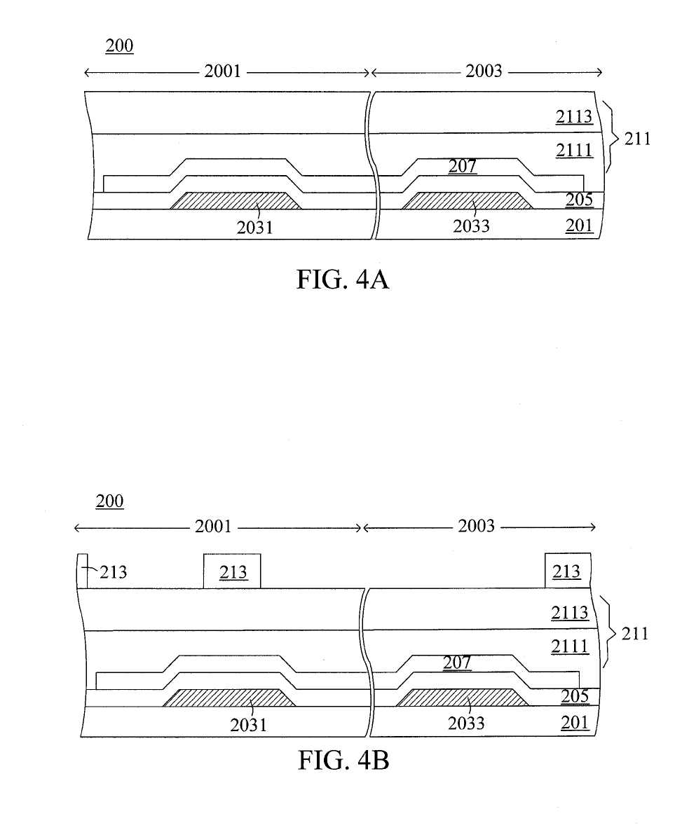

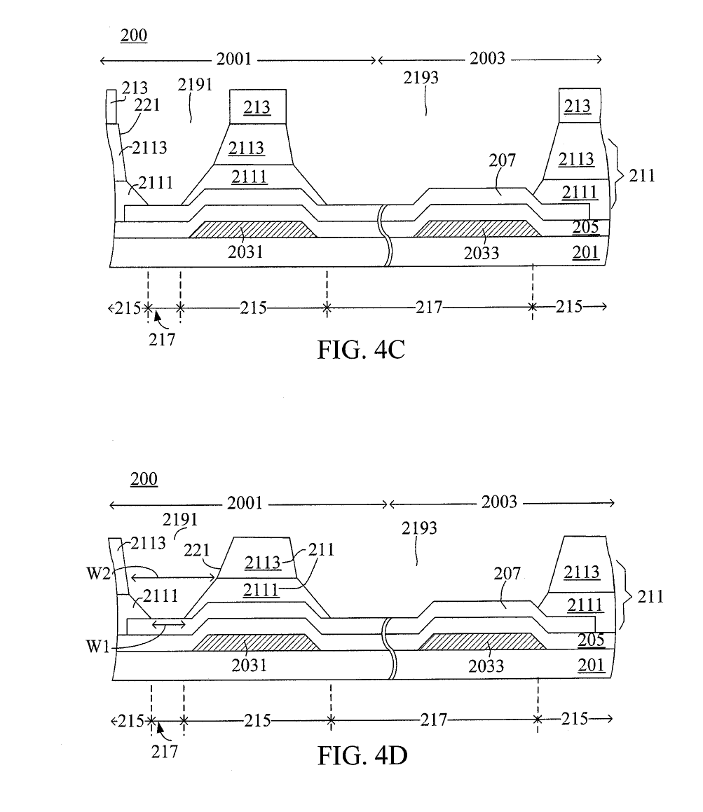

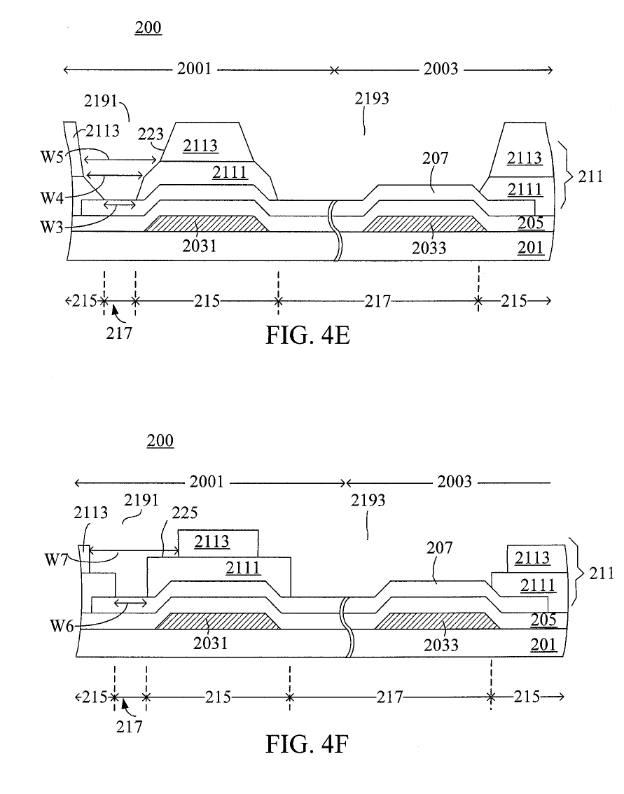

Subsequently, referring to FIG. 4A, a dielectric layer 211, which comprises a second dielectric layer 2111 and a third dielectric layer 2113, is formed on the underlayer 209. The second dielectric layer 2111 and the third dielectric layer 2113 may be formed of a material selected from the group of oxides, nitrides, other appropriate dielectric materials or a composite of these dielectric materials. The second dielectric layer 2111 and the third dielectric layer 2113 may be formed of a same material or formed of different materials to present different etching selectivity. For purpose of description, a composite layer is taken as an example of the dielectric layer 211 in the following description, wherein the third dielectric layer 2113 is an oxide layer and the second dielectric layer 2111 is a nitride layer.

As shown in FIG. 4A, through an appropriate process such as the aforesaid PECVD process, a nitride layer and an oxide layer are sequentially formed on the substrate 201 as the second dielectric layer 2111 and the third dielectric layer 2113 respectively. Traditionally, an appropriate material such as SiH₄, ammonia (NH₃) or nitrogen (N₂) is used to form a nitride layer through an appropriate process such as PECVD. Typically, the nitride layer has a thickness substantially ranging from 1000 Å to 3500 Å, and preferably, from 2000 Å to 2500 Å.

Next, portions of the second dielectric layer 2111 and the third dielectric layer 2113 are removed to leave the second dielectric layer 2111 partially on the patterned semiconductor layer 207. This may be accomplished by a lithography and etching process. Briefly speaking, this includes but is not limited to the following steps. As illustrated in FIG. 4B, a layer of photo-sensitive material, i.e., the so-called photoresist layer (an intermediate structure up to this step is not shown), is coated on a surface of the third dielectric layer 2113. Then, a light ray is allowed to irradiate the photoresist layer via a mask for exposure. Here, because the mask with a pattern including active regions thereon will allow a portion of the light ray to pass through and irradiate the photoresist layer. The exposure selectivity is then achieved in the photoresist layer and thus, the pattern of the mask is copied entirely onto the photoresist layer. Finally, a suitable developer is used to remove a portion of the photoresist to obtain a desired pattern of the photoresist layer. As a result, a patterned photoresist layer 213 is formed on the third dielectric layer 2113.

Referring to FIG. 4C, an etching process is then performed to remove portions of the third dielectric layer 2113 and the underlying second dielectric layer 2111 uncovered by the patterned photoresist layer 213, thereby to define the openings 2191 and 2193 in the second dielectric layer 2111 and the third dielectric layer 2113. Optionally, the etching process includes selective use of a wet etching process, a dry etching process, or a combination thereof. In this embodiment, a combination of the wet etching process and the dry etching process will be taken as an example for description. As shown in FIG. 4C, the third dielectric layer 2113 is removed in predetermined regions of the openings 2191 and 2193 through dry etching (e.g., ion bombardment). Then, a wet etching process is performed with an appropriate etchant solution to remove the second dielectric layer 2111.

Next, referring to FIG. 4D, the remaining patterned photoresist layer 213 is completely removed. In the structure depicted in FIG. 4D, the second dielectric layer 2111 and the third dielectric layer 2113 define a covered region 215 and an uncovered region 217 on the patterned semiconductor layer 207, in which the covered layer 215 is covered by the remaining second dielectric layer 2111 and the uncovered region 217 exposes a portion of the patterned semiconductor layer 207. For example, the uncovered region 217, the second dielectric layer 2111 and the third dielectric layer 2113 jointly define an opening 2191. Both the second dielectric layer 2111 and the third dielectric layer 2113 have a side wall 221 facing the opening 2191 respectively.

The different etching selectivity of the second dielectric layer 2111 and the third dielectric layer 2113 causes the side wall 221 form a lateral contour, i.e., the opening 2191 has a topography wide at the top and narrow at the bottom. The side wall 221 comprises an upper side wall with an upper slope in the third dielectric layer 2113 and a lower side wall with an under slope in the second dielectric layer 2111. To form a doped structure with different doping concentrations in this invention, the upper slope is designed with a value no less than that of the under slope, so that the second dielectric layer 2111 covers the patterned semiconductor layer 207 in varied thickness at the boundary between the openings 2191, 2193 and the second dielectric layer 2111. The side wall 221 of FIG. 4D illustrates such an aspect. In this embodiment, the opening 2191 has a bottom lateral dimension W1 and a top lateral dimension W2 greater than W1, so a portion of the second dielectric layer 2111 is exposed and an edge of the opening 2191 is approximately aligned with an edge of the gate 2031.

In other embodiments, the side wall 221 may have two under slopes in the second dielectric layer 2111, namely a first under slope at the top portion and a second under slope at the bottom portion. The first under slope has a value less than that of the second under slope, as illustrated by the side wall 223 in FIG. 4E. In this embodiment, the opening 2191 has a bottom lateral dimension W3 and two top lateral dimensions W4, W5. The bottom lateral dimension W3 is less than the top lateral dimensions W4, W5, so a portion of the second dielectric layer 2111 is exposed and an edge of the opening 2191 is approximately aligned with an edge of the gate 2031. Furthermore, the side wall may have a step-like lateral contour, as shown by the side wall 225 in FIG. 4F. In this embodiment, the opening 2191 has a bottom lateral dimension W6 and a top lateral dimension W7. The bottom lateral dimension W6 is less than the top lateral dimension W7, so a portion of the second dielectric layer 2111 is exposed and an edge of the opening 2191 is approximately aligned with an edge of the gate 2031. Hence, those of ordinary skill in the art will appreciate how to make appropriate modifications on the lateral contour of the side wall after the doped structure with different doping concentrations is formed. For purpose of description, the side wall 223 of FIG. 4E will be taken as an example to describe an exemplary example of forming a doped structure with different doping concentrations through a self-aligned doping process.

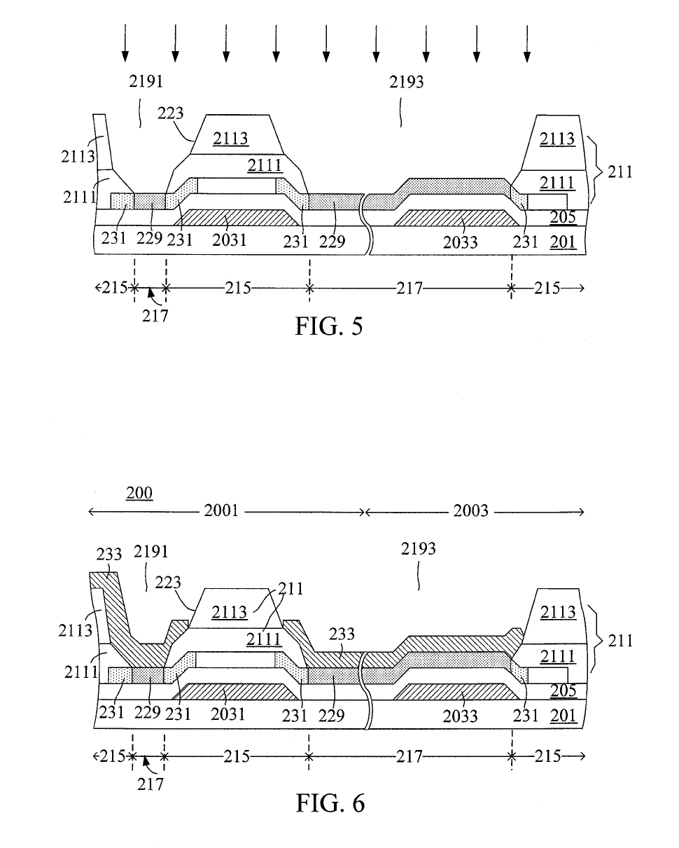

Subsequent to the formation of the second dielectric layer 2111 shown in FIG. 4E, an ion implantation step is performed to obtain a doped structure in the patterned semiconductor layer 207. As shown in FIG. 5, after the ion implantation step has been performed once or twice on the pixel structure 200, the ions that are implanted are adapted to form a heavily doped structure 229 in the patterned semiconductor layer 207 of the uncovered region 217 via the opening 2191. Since a portion of the ions will be absorbed by the second dielectric layer 2111, a lightly doped structure 231 is formed in the patterned semiconductor layer 207 of the covered region 215 covered by the exposed second dielectric layer 2111. On the other hand, portions of the covered region 215 covered by both the second dielectric layer 2111 and the third dielectric layer 2113 will not be implanted with ions. Likewise, a heavily doped structure 229 and a lightly doped structure 231 will also be formed in the opening 2193 after the ion implantation step.

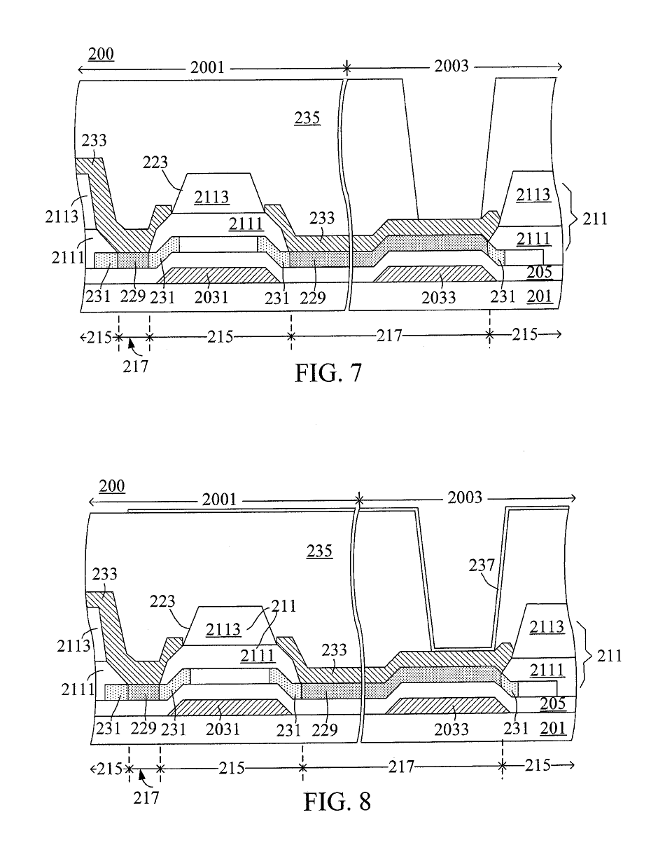

Referring next to FIG. 6, a second patterned conductive layer 233, which is electrically connected to the patterned semiconductor layer 207 via the openings 2191 and 2193, is formed on the third dielectric layer 2113 and within the openings 2191 and 2193. The second patterned conductive layer 233 within the opening 2193 is formed at least above a first capacitor electrode 2033 to serve as a second capacitor electrode aligned with the first capacitor electrode 2033. As another result of this step, the second patterned conductive layer 233 will also cover portions of the TFT region 2001 and the capacitor region 2003 to serve as a part of the TFT to electrically connect the second capacitor electrode to the TFT. As shown in FIG. 7, a passivation layer 235 is formed on the substrate 201 to cover the second patterned conductive layer 233 and the third dielectric layer 2113. However, a portion of the second patterned conductive layer 233 within the opening 2193 is exposed. Finally, as shown in FIG. 8, a pixel electrode 237 is formed on the passivation layer 235 to be electrically connected to the second patterned conductive layer 233.

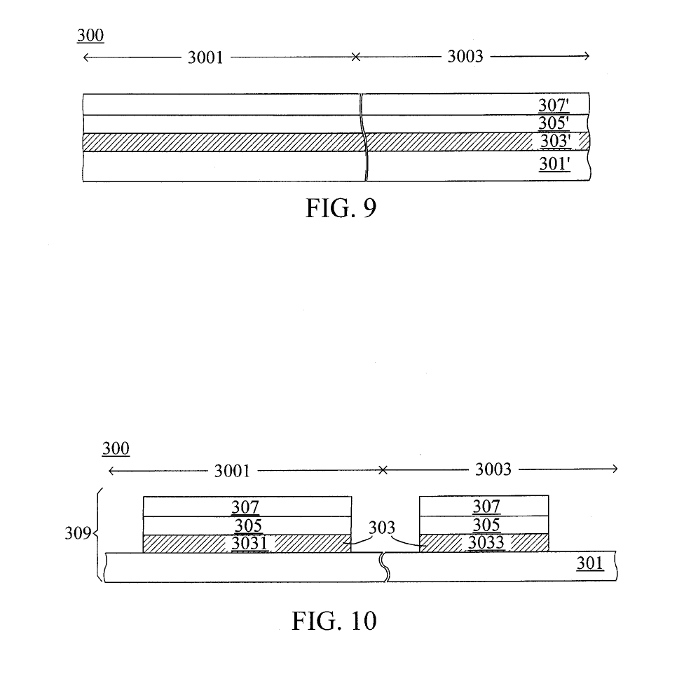

It should be noted that the underlayer 209 depicted in FIG. 3 may also be obtained through a half-tone mask. Hereinafter, a second embodiment briefly describes a process of forming a pixel structure in an LCD by use of a half-tone mask according to the method of this invention, including the formation of a doped structure in the pixel structure. Initially, referring to FIG. 9, a TFT region 3001 and a capacitor region 3003 are defined in a pixel structure 300. Subsequently, a first conductive layer 303′, a first dielectric layer 305′ and a semiconductor layer 307′ are sequentially formed on the substrate 301′. For example, the first conductive layer 303′ may be formed through a sputtering process, while the first dielectric layer 305′ and the semiconductor layer 307′ may be formed respectively through a chemical vapor deposition (CVD) process.

As shown in FIG. 10, a photoresist layer in a varied thickness is formed by use of a half-tone mask in a single masking process, and is formed into patterns with two different dimensions in an etching step. As a result, the first conductive layer 303′, the first dielectric layer 305′ and the semiconductor layer 307′ form the first patterned conductive layer 303, the first patterned dielectric layer 305 and the patterned semiconductor layer 307 respectively. In some regions, the patterned semiconductor layer 307 has a pattern smaller than those of the first patterned dielectric layer 305 and the first patterned conductive layer 303. The half-tone mask process is well-known in the art and therefore, steps thereof will not be described in detail herein. The first patterned conductive layer 303 comprises a gate 3031 and a first capacitor electrode 3033. Upon completion of the half-tone mask process, an underlayer 309 is obtained. The underlayer 309 comprises the patterned semiconductor layer 307, the first patterned dielectric layer 305, the first patterned conductive layer 303 and the substrate 301 from top to bottom. On the other hand, in a portion of regions other than the TFT region 3001 and the capacitor region 3003, only the first patterned dielectric layer 305 and the first patterned conductive layer 303 are included from top to bottom for use as conductors (not shown).

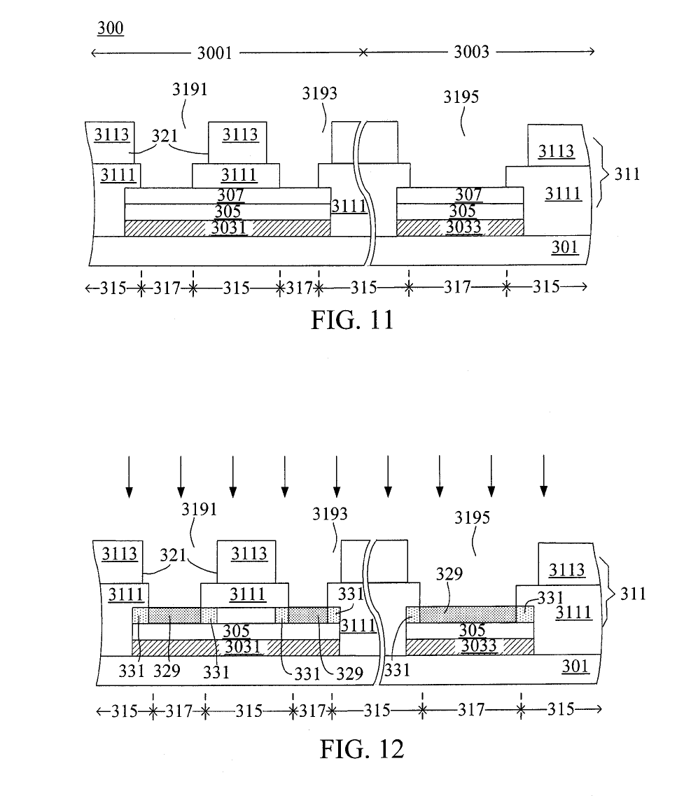

As shown in FIG. 11, a second dielectric layer 3111 and a third dielectric layer 3113 are partially formed on the underlayer 309 to define a covered region 315 and an uncovered region 317 on the patterned semiconductor layer 307, and openings 3191, 3193 and 3195 are defined in the second dielectric layer 3111 and the third dielectric layer 3113. For example, both the second dielectric layer 3111 and the third dielectric layer 3113 have a side wall facing the opening 3191 respectively. The second dielectric layer 3111, the third dielectric layer 3113, and the openings 3191, 3193 and 3195 can be formed in the manners disclosed in the first embodiment and thus will not be further described herein. For purpose of description, still with reference to an example where the third dielectric layer 3113 is an oxide layer, the second dielectric layer 3111 is a nitride layer and the side wall 321 is as shown in FIG. 4F, a process of forming a doped structure with different doping concentrations through a self-aligned doping process will be described hereinafter.

Subsequent to the formation of the second dielectric layer 3111 and the third dielectric layer 3113, an ion implantation step is performed once or twice to obtain a doped structure. Illustrated in FIG. 12, as in the first embodiment, the patterned semiconductor layer 307 exposed via the uncovered region 317 forms a heavily doped structure 329, and portions of the covered region 315 covered by only the exposed second dielectric layer 3111 forms a lightly doped structure 331. In contrast, the portions of the covered region 315 covered by both the second dielectric layer 3111 and the third dielectric layer 3113 will not be implanted with ions. Likewise, a heavily doped structure 329 and a lightly doped structure 331 will also be formed in the openings 3193 and 3195 in the ion implantation step.

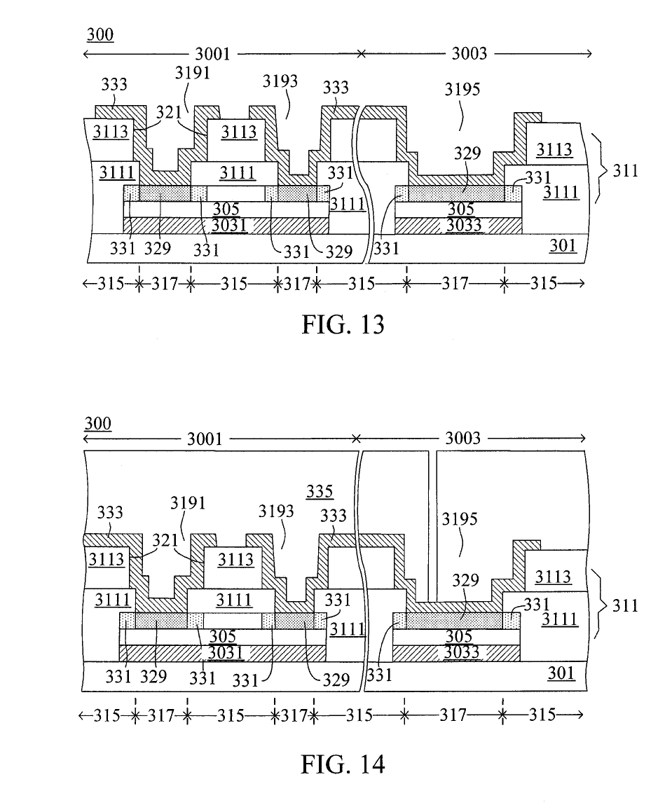

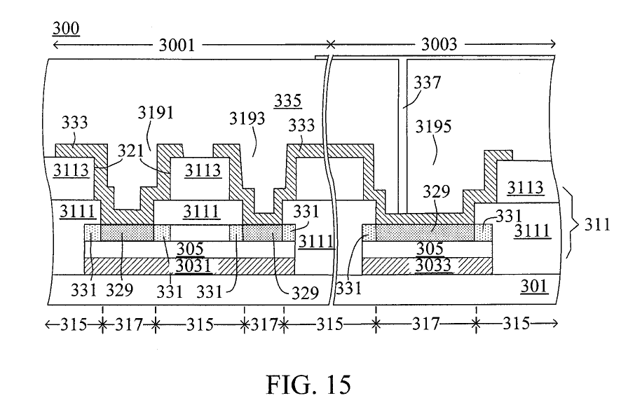

Referring next to FIG. 13, a second patterned conductive layer 333, which is electrically connected to the patterned semiconductor layer 307 via the openings 3191, 2193 and 3195, is formed on the third dielectric layer 3113 and within the openings 3191, 3193 and 3195. The second patterned conductive layer 333 is formed at least above a first capacitor electrode 3033 to serve as a second capacitor electrode aligned with the first capacitor electrode 3033. The second patterned conductive layer 333 may be made of molybdenum (Mo), tungsten (W), chromium (Cr), aluminum (Al), copper (Cu), or an alloy or a stack thereof, or other appropriate materials. As another result of this step, the second patterned conductive layer 333 will cover both a portion of the TFT region 3001 and the capacitor region 3003 to form a second patterned conductive layer 333 within the openings 3193 and 3195 to electrically connect the TFT to the second capacitor electrode. Referring to FIG. 14, a passivation layer 335 is formed throughout the substrate 201 to cover the second patterned conductive layer 333 and the third dielectric layer 3113 but expose a portion of the second patterned conductive layer 333 above the first capacitor electrode 3033. Finally, referring to FIG. 15, a pixel electrode 337 is formed on the passivation layer 335 to be electrically connected to the second patterned conductive layer 333.

In the first and the second embodiments described above, the second dielectric layer and the third dielectric layer may also be made of a single material and then partially be formed with an opening structure with an upper side wall and a lower side wall through, for example, an anisotropic etching process. The upper side wall has an upper slope, while the lower side wall has an under slope, the upper slope is no less than the under slope. Therefore, the dielectric structure jointly formed by the second dielectric layer 3111 and the third dielectric layer 3113 covers the patterned semiconductor layer 307 in varied thicknesses, which is beneficial to the subsequent formation of the doped structure of this invention.

In summary, this invention provides a method of forming a doped structure in a bottom-gate TFT without the need of an additional mask. By using a self-aligned doping process, this invention is able to obtain a desired doped structure with reduced manufacturing costs. The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A manufacturing method of a thin-film-transistor (TFT) structure in a liquid crystal display (LCD), the method comprising the steps of:
(a) forming a gate on a substrate;
(b) forming a first dielectric layer to cover the gate;
(c) forming a patterned semiconductor layer on the first dielectric layer overlapping the gate;
(d) sequentially forming a second dielectric layer and a third dielectric layer on the patterned semiconductor layer to partially expose the patterned semiconductor layer on two sides of the gate by forming a plurality of openings, each of the openings being provided with a bottom lateral dimension and at least one top lateral dimension;
wherein the bottom lateral dimension is defined by the second dielectric layer, the at least one top lateral dimension is defined by the third dielectric layer, the bottom lateral dimension is smaller than the at least one top lateral dimension to partially expose the second dielectric layer, and an edge of the opening defined by the second dielectric layer is aligned approximately with an edge of the gate; and
(e) forming a heavily doped region in the exposed patterned semiconductor layer corresponding to the openings and forming a lightly doped region in the patterned semiconductor layer under the exposed second dielectric layer by a doping process.

2. The method as claimed in claim 1, wherein each of the opening in the second dielectric layer and the third dielectric layer has a side wall, wherein the side wall of the third dielectric layer is provided with an upper slope, and the side wall of the second dielectric layer is provided with a under slope; a value of the upper slope is not smaller than a value of the under slope.

3. The method as claimed in claim 1, wherein the step of forming a plurality of openings in step (d) comprises the steps of:
forming a patterned photoresist layer on the third dielectric layer;
etching the third dielectric layer and the second dielectric layer by using a wet etching process; and
removing the patterned photoresist layer.

4. The method as claimed in claim 3, further comprising etching the third dielectric layer and the second dielectric layer by using a dry etching process before the step of using the wet etching process.

5. The method as claimed in claim 3, wherein the second dielectric layer and the third dielectric layer have different etching selectivity.

6. A manufacturing method of a pixel structure in a liquid crystal display, the method comprising the steps of:
(a) forming a first patterned conductive layer on a substrate, in which the first patterned conductive layer is formed with a gate and a first capacitor electrode;
(b) forming a first dielectric layer to cover the gate and the first capacitor electrode;
(c) forming a patterned semiconductor layer on the first dielectric layer to overlap the gate and the first capacitor electrode;
(d) sequentially forming a second dielectric layer and a third dielectric layer on the patterned semiconductor layer, and partially exposing the patterned semiconductor layer on two sides of the gate by forming a plurality of openings, each of the openings is provided with a bottom lateral dimension and at least one top lateral dimension;
wherein the bottom lateral dimension is defined by the second dielectric layer, the at least one top lateral dimension is defined by the third dielectric layer, the bottom lateral dimension is smaller than the at least one top lateral dimension to partially expose the second dielectric layer, an edge of the opening defined by the second dielectric layer is aligned approximately with an edge of the gate;
(e) forming a heavily doped region in the exposed patterned semiconductor layer corresponding to the openings and forming a lightly doped region in the patterned semiconductor layer under the exposed second dielectric layer by a doping process;
(f) forming a second patterned conductive layer on the third dielectric layer and within the openings, wherein the second patterned conductive layer includes a second capacitor electrode being aligned with the first capacitor electrode;
(g) forming a passivation layer to cover the second patterned conductive layer and the third dielectric layer; and
(h) forming a pixel electrode on the passivation layer, in which the pixel electrode is electrically connected to the second patterned conductive layer via the opening.

7. The method as claimed in claim 6, wherein the step of forming a plurality of openings in step (d) comprises the steps of:
forming a patterned photoresist layer on the third dielectric layer;
etching the third dielectric layer and the second dielectric layer by using a wet etching process; and
removing the patterned photoresist layer.

8. The method as claimed in claim 7, further comprises etching the third dielectric layer and the second dielectric layer by using a dry etching process before the step of using the wet etching process.

9. The method as claimed in claim 7, wherein the second dielectric layer and the third dielectric layer have different etching selectivity.

10. A thin-film-transistor structure on a substrate, the thin-film-transistor comprising:
a gate formed on the substrate;
a first dielectric layer covering the gate;
a patterned semiconductor layer formed on the first dielectric layer to overlap the gate; and
a second dielectric layer and a third dielectric layer partially formed on the patterned semiconductor layer to define a covered region and an uncovered region on the patterned semiconductor layer, in which the uncovered region, the second dielectric layer and the third dielectric layer jointly define at least one opening; and the opening is formed with a bottom lateral dimension and at least one top lateral dimension;
wherein the bottom lateral dimension is defined by the second dielectric layer, the at least one top lateral dimension is defined by the third dielectric layer, the bottom lateral dimension is smaller than the at least one top lateral dimension to partially expose a part of the second dielectric layer being uncovered by the third dielectric layer, an edge of the opening defined by the second dielectric layer is aligned approximately with an edge of the gate;
wherein the patterned semiconductor layer includes a heavily doped structure in the uncovered region and a lightly doped structure under the uncovered second dielectric layer.

11. The thin-film-transistor structure as claimed in claim 10, wherein the second dielectric layer is formed with a side wall having an under slope; the third dielectric layer is also formed with a side wall having an upper slope; and the side walls face the opening, and a value of the upper slope is not smaller than a value of the under slope.

12. The thin-film-transistor structure as claimed in claim 11, wherein the side wall of the second dielectric layer has a first under slope in a lower portion of the side wall and a second under slope in an upper portion of the side wall, and a value of the first under slope is smaller than a value of the second under slope.

13. The thin-film-transistor structure as claimed in claim 10, wherein the second dielectric layer is formed with a side wall and the third dielectric layer is also formed with a side wall; the side walls face the opening and form a lateral contour at the second dielectric layer, and the lightly doped structure is under the lateral contour of the second dielectric layer.

14. The thin-film-transistor structure as claimed in claim 10, wherein the second dielectric layer and the third dielectric layer are made of different materials.

15. The thin-film-transistor structure as claimed in claim 14, wherein the second dielectric layer is a nitride layer and the third dielectric layer is an oxide layer.

16. The thin-film-transistor structure as claimed in claim 15, wherein a thickness of the nitride layer is substantially between 1000 to 3500 angstrom (Å).

17. The thin-film-transistor structure as claimed in claim 15, wherein a thickness of the nitride layer is substantially between 2000 to 2500 angstrom (Å).

18. A pixel structure formed on a substrate, the pixel structure comprising:
a first patterned conductive layer, being formed on the gate with a gate and a first capacitor electrode;
a first dielectric layer, being formed to cover the gate and the first capacitor electrode;
a patterned semiconductor layer, being formed to overlap the first dielectric layer on the gate and the first capacitor electrode;
a second dielectric layer and a third dielectric layer, partially formed on the patterned semiconductor layer to define a covered region and an uncovered region on the patterned semiconductor layer; in which the uncovered region, the second dielectric layer and the third dielectric layer jointly define a opening; and the opening has a bottom lateral dimension and at least one top lateral dimension;
wherein the bottom lateral dimension is defined by the second dielectric layer, the at least one top lateral dimension is defined by the third dielectric layer, the bottom lateral dimension is smaller than the at least one top lateral dimension to partially expose the second dielectric layer, an edge of the opening defined by the second dielectric layer is aligned approximately with an edge of the gate;
wherein the patterned semiconductor layer includes a heavily doped structure in the uncovered region and a lightly doped structure under the uncovered second dielectric layer;
a second patterned conductive layer, formed both on the third dielectric layer and within the openings with a second capacitor electrode being aligned with the first capacitor electrode;
a passivation layer, covering the second patterned conductive layer and the third dielectric layer; and
a pixel electrode, being formed on the passivation layer and being electrically connected to the second patterned conductive layer.

19. The pixel structure as claimed in claim 18, wherein the second dielectric layer is formed with a side wall having a under slope and the third dielectric layer also is formed with a side wall having an up slope; wherein the side walls face the opening, and a value of the up slope is not smaller than a value of the under slope.

20. The pixel structure as claimed in claim 19, wherein the side wall of the second dielectric layer is formed with a first under slope and a second under slope, and a value of the first under slope is smaller than a value of the second under slope.

21. The pixel structure as claimed in claim 18, wherein the second dielectric layer is formed with a side wall and the third dielectric layer is also formed with a side wall; the side walls face the opening and form a lateral contour, and the implant ions enters low portion under the second dielectric layer via the lateral contour.

22. The pixel structure as claimed in claim 18, wherein the second dielectric layer and the third dielectric layer are made of different materials.

23. The pixel structure as claimed in claim 22, wherein the second dielectric layer is a nitride layer and the third dielectric layer is an oxide layer.

24. The pixel structure as claimed in claim 23, wherein a thickness of the nitride layer is substantially between 1000 to 3500 angstrom (Å).

25. The pixel structure as claimed in claim 23, wherein a thickness of the nitride layer is substantially between 2000 to 2500 angstrom (Å).
